(19) United States
(12) Patent Application Publication
(10) Pub. No.: US 2026/0156997 A1
(43) Pub. Date: Jun. 4, 2026

(54) DISPLAY DEVICE

(71) Applicant: LG Display Co., Ltd., Seoul (KR)

(72) Inventor: HEUMEIL BAEK, Seoul (KR)

(73) Assignee: LG Display Co., Ltd., Seoul (KR)

(21) Appl. No.: 19/332,941

(22) Filed: Sep. 18, 2025

(30) Foreign Application Priority Data
Dec. 3, 2024 (KR) 10-2024-0177330

(51) Int. Cl. H10H 29/37; H01L 25/075

(52) U.S. Cl. CPC H10H 29/37; H10W 90/00

(57) ABSTRACT

A display device includes a substrate in which a plurality of pixels each including a plurality of sub pixels are defined. The display device further includes a plurality of light emitting diodes disposed in each of the plurality of sub pixels and having a first light emitting diode and a second light emitting diode that are configured emit the same color light. The display device further includes a first bank spaced apart from the plurality of light emitting diodes so as to enclose the first light emitting diode and the second light emitting diode. The display device further includes a second bank disposed on the first bank and configured to enclose the second light emitting diode. The first and second banks include a black material.

### CROSS-REFERENCE TO RELATED APPLICATIONS

This application claims priority to Korean Patent Application No. 10-2024-0177330, filed on Dec. 3, 2024, in the Republic of Korea, the entire disclosure of which is hereby expressly incorporated by reference into the present application.

### BACKGROUND

### Field

The present disclosure relates to a display device, and more particularly to a display device in which a viewing angle is adjustable.

### Description of the Related Art

As the technology in modern society develops, display devices are used in various ways to provide information to users. The display devices are included in not only electronic signs which simply transmit visual information in one direction, but also various electronic devices which need a higher level of technology to check the user's input and provide information in response to the checked input.

For example, a display device is included in a vehicle to provide various information to a driver and a passenger of the vehicle. However, the display device of the vehicle needs to appropriately display contents without interrupting the operation of the vehicle. For example, the display device needs to limit the display of the contents which can reduce the concentration on the driving while the vehicle is in operation.

### SUMMARY OF THE DISCLOSURE

An object to be achieved by the present disclosure is to provide a display device which is capable of adjusting a viewing angle by utilizing a black bank.

Another object to be achieved by the present disclosure is to provide a display device in which a viewing angle characteristic varies depending on a height of a black bank.

Still another object to be achieved by the present disclosure is to provide a display device in which recognition of spots due to a viewing angle deviation is minimized.

Objects of the present disclosure are not limited to the above-mentioned objects, and other objects, which are not mentioned above, can be clearly understood by those skilled in the art from the following descriptions.

According to an aspect of the present disclosure, there is provided a display device. The display device includes a substrate in which a plurality of pixels each including a plurality of sub pixels is defined. The display device further includes a plurality of light emitting diodes which is disposed in each of the plurality of sub pixels and includes a first light emitting diode and a second light emitting diode which emit the same color light. The display device further includes a first bank which is spaced apart from the plurality of light emitting diodes so as to enclose the first light emitting diode and the second light emitting diode and includes a black material. The display device further includes a second bank which is disposed on the first bank, is disposed so as to enclose the second light emitting diode, and includes the black material.

According to another aspect of the present disclosure, there is provided a display device. The display device includes a substrate in which a plurality of pixels including a plurality of sub pixels is defined. The display device further includes a plurality of light emitting diodes which is disposed in each of the plurality of pixels and includes a first light emitting diode and a second light emitting diode which emit the same color light. The display device further includes a black bank which is disposed so as to enclose the plurality of light emitting diodes in each of the plurality of pixels. The plurality of sub pixels includes a first area in which the first light emitting diode is disposed, and a second area in which a second light emitting diode emitting the same color light as the first light emitting diode is disposed. The black bank has different heights in the first area and the second area, respectively.

Other detailed matters of the example embodiments of the present disclosure are included in the detailed description and the drawings.

According to the example embodiments of the present disclosure, the viewing angle is adjustable by utilizing a black bank.

According to the example embodiments of the present disclosure, a height of a black bank is adjusted to implement various viewing angle modes.

According to the example embodiments of the present disclosure, a process of placing a separate lens for adjusting a viewing angle is omitted to implement process optimization by simplifying the processes.

According to the example embodiments of the present disclosure, black banks are randomly disposed to minimize the recognition of spots caused by the viewing angle deviation.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is an example of a display device according to an example embodiment of the present disclosure;

FIG. 2 is a schematic diagram of a display device according to an example embodiment of the present disclosure;

FIG. 3 is an enlarged plan view of an active area of a display device according to an example embodiment of the present disclosure;

FIG. 4A is a cross-sectional view taken along A-A′ of FIG. 3 according to an example of the present disclosure;

FIG. 4B is a cross-sectional view taken along B-B′ of FIG. 3 according to an example of the present disclosure;

FIG. 5 is an enlarged plan view of a predetermined unit pixel of a display device according to an example embodiment of the present disclosure;

FIG. 6 is a distribution chart of a viewing angle of a predetermined unit pixel of a display device according to an example embodiment of the present disclosure; and

FIG. 7 is a cross-sectional view of a sub pixel of a display device according to another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms such as “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the specification. Further, the term “can” fully encompasses all the meanings and coverages of the term “may” and vice versa.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All the components of each display device/apparatus according to all embodiments of the present disclosure are operatively coupled and configured.

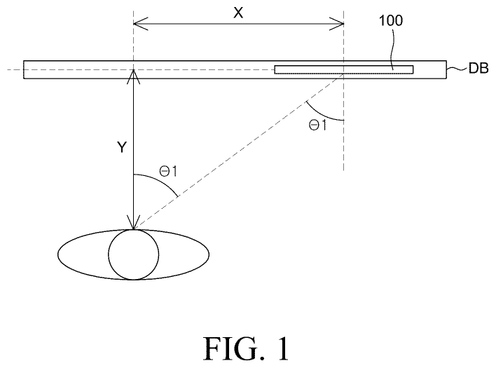

FIG. 1 is an example of a display device according to an example embodiment of the present disclosure.

Referring to FIG. 1, a display device 100 can be disposed in at least a part of a dash board DB of a vehicle. The dash board DB of the vehicle includes a configuration which is disposed on a front surface of a front seat of the vehicle. For example, on the dash board DB of the vehicle, an input configuration for manipulating various functions (for example, an air-conditioner, an audio system, or a navigation system) in the vehicle can be disposed.

The display device 100 can be disposed in the front direction of a front passenger seat of the dash board DB of the vehicle. For example, the display device 100 can be a co-driver display (CDD). Accordingly, the display device 100 according to the example embodiment of the present disclosure is disposed on the dash board DB of the vehicle to provide convenience of a passenger in the front passenger seat. For example, the display device 100 can provide information which is irrelevant to the vehicle operation, for example, information about entertainment, such as dramas, movies, or music.

The display device 100 can be disposed in a side direction of the driver seat. For example, an angle between a normal line of the display device 100 and a driver of the driver seat at the center of the display device 100 can be a first angle θ1. For example, when a vertical distance between the display device 100 and the driver is Y and a horizontal distance between the driver and the center of the display device 100 is X, tan θ1=X/Y. For example, tan θ1 can be determined by a vertical distance between the display device 100 and the driver and a horizontal distance between the driver and the center of the display device 100. Therefore, tan θ1 can vary depending on a vehicle structure and generally have a value of 50 degrees or larger and 60 degrees or smaller.

The display device 100 can selectively provide images of the display device 100 to the driver according to a mode. For example, in a first mode in which the vehicle is stopped, the display device 100 can emit light having a viewing angle larger than the first angle θ1 toward the driver seat. For example, in the first mode, the display device 100 can emit light having a viewing angle of approximately 80° toward the driver seat. Accordingly, in the first mode, the driver and the passenger can watch the image of the display device 100 together.

Further, in a second mode in which the vehicle is being driven, the display device 100 can emit light having a viewing angle smaller than the first angle θ1 toward the driver seat. For example, in the second mode, the display device 100 can emit light having a viewing angle of approximately 40° toward the driver seat. Accordingly, in the second mode, the passenger can watch the image of the display device 100, but the driver can be restricted from watching the image of the display device 100.

Therefore, when the display device 100 is driven in the first mode in a state in which the vehicle is stopped, the driver and the passenger can watch the image of the display device 100 together. Further, when the display device 100 is driven in the second mode in a state in which the vehicle is being driven, only the passenger can watch the image of the display device 100 to ensure the safety of the vehicle operation.

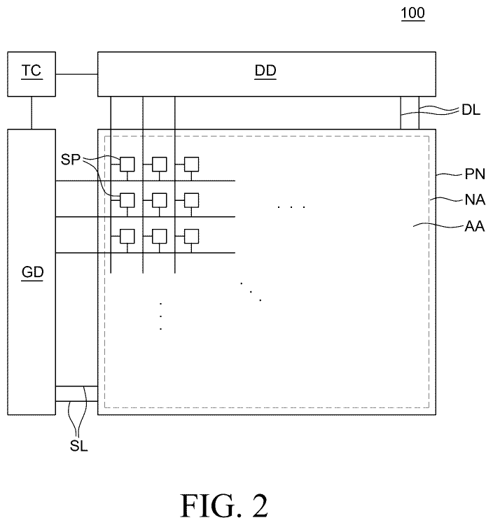

FIG. 2 is a schematic diagram of a display device according to an example embodiment of the present disclosure. In FIG. 2, for the convenience of description, among various components of the display device 100, a display panel PN, a gate driver GD, a data driver DD, and a timing controller TC are illustrated.

Referring to FIG. 2, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 2, it is illustrated that one gate driver GD is disposed to be spaced apart from one side of the display panel PN, the number of the gate drivers GD and the placement thereof are not limited thereto.

The data driver DD supplies a data voltage to a plurality of data lines DL according to a plurality of data control signals and image data supplied from the timing controller TC. The data driver DD can convert the image data into a data voltage using a reference gamma voltage and supply the converted data voltage to the plurality of data lines DL.

The timing controller TC aligns image data input from the outside to supply the image data to the data driver DD. The timing controller TC can generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user. The display panel PN can include a substrate in which a plurality of pixels each including the plurality of sub pixels SP is defined. In the display panel PN, the plurality of scan lines SL and the plurality of data lines DL intersect each other and the plurality of sub pixels SP can be formed at intersections of the scan lines SL and the data lines DL.

In the display panel PN, an active area AA and a non-active area NA can be defined.

The active area AA is an area in which images are displayed in the display device 100. In the active area AA, a plurality of sub pixels SP which configures a plurality of pixels PX and a pixel circuit for driving the plurality of sub pixels SP can be disposed. The plurality of sub pixels SP is a minimum unit which configures the active area AA and n sub pixels SP can form one pixel PX. In each of the plurality of sub pixels SP, a thin film transistor for driving the plurality of light emitting diodes can be disposed. The plurality of light emitting diodes can be defined in different manners depending on the type of the display panel PN. For example, when the display panel PN is an inorganic light emitting display panel PN, the light emitting diode can be a light emitting diode (LED) or a micro light emitting diode (micro LED).

In the active area AA, a plurality of signal lines which transmits various signals to the plurality of sub pixels SP is disposed. For example, the plurality of signal lines can include a plurality of data lines DL which supplies a data voltage to each of the plurality of sub pixels SP and a plurality of scan lines SL which supplies a scan signal to each of the plurality of sub pixels SP. The plurality of scan lines SL extends to one direction in the active area AA to be connected to the plurality of sub pixels SP and the plurality of data lines DL extends to a direction different from the one direction in the active area AA to be connected to the plurality of sub pixels SP. In addition, in the active area AA, a low potential power line and a high potential power line can be further disposed, but are not limited thereto.

The non-active area NA is an area where images are not displayed so that the non-active area NA can be defined as an area extending from the active area AA. In the non-active area NA, a link line which transmits a signal to the sub pixel SP of the active area AA, a pad electrode, or a driving IC, such as a gate driver IC or a data driver IC, can be disposed.

In the meantime, the non-active area NA can be located on a rear surface of the display panel PN, for example, a surface on which the sub pixels SP are not disposed or can be omitted, and is not limited as illustrated in the drawing.

In the meantime, a driver, such as a gate driver GD, a data driver DD, and a timing controller TC, can be connected to the display panel PN in various ways. For example, the gate driver GD can be mounted in the non-active area NA in a gate in panel (GIP) manner or mounted between the plurality of sub pixels SP in the active area AA in a gate in active area (GIA) manner.

For example, the data driver DD and the timing controller TC are formed in separate flexible film and printed circuit board. The display panel PN can be electrically connected to the data driver DD and the timing controller TC by bonding the flexible film and the printed circuit board to the pad electrode formed in the non-active area NA of the display panel PN.

As another example, when the gate driver GD is mounted in the active area AA in the GIA manner and a side line which connects the signal line on the front surface of the display panel PN to the pad electrode on a rear surface of the display panel PN is formed to bond the flexible film and the printed circuit board onto a rear surface of the display panel PN, the non-active area NA can be minimized on the front surface of the display panel PN. Therefore, when the gate driver GD, the data driver DD, and the timing controller TC are connected to the display panel PN as described above, a zero bezel with substantially no bezel can be implemented.

Hereinafter, a display panel PN of a display device 100 according to an example embodiment of the present disclosure will be described in more detail.

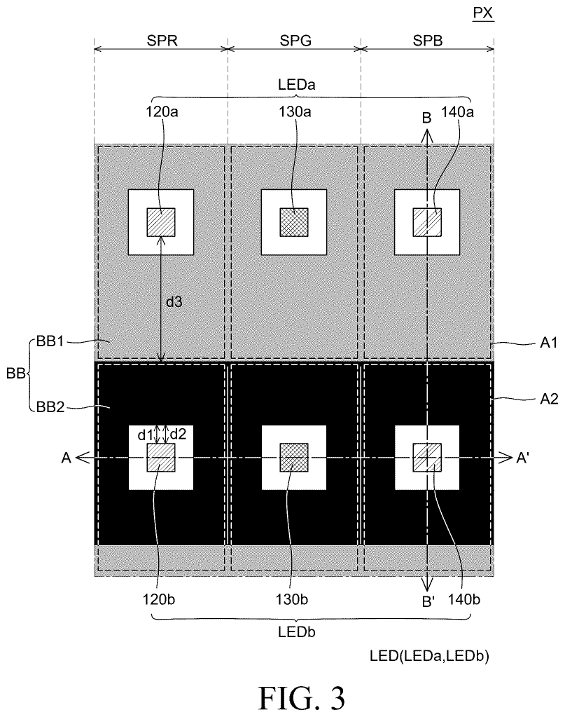

FIG. 3 is an enlarged plan view of an active area of a display device according to an example embodiment of the present disclosure.

Referring to FIG. 3, the display device 100 according to the example embodiment of the present disclosure can include a plurality of pixels PX each including a plurality of sub pixels SP. Each of the plurality of sub pixels SP includes a plurality of light emitting diodes and a plurality of pixel circuits to independently emit light. One pixel PX can include one or more red sub pixels SPR, one or more green sub pixels SPG, and one or more blue sub pixels SPB. In the meantime, the plurality of pixels PX can further include a sub pixel SP which emits another color light, other than the red sub pixel SPR, the green sub pixel SPG, and he blue sub pixel SPB, but is not limited thereto.

In each of the plurality of pixels PX, a plurality of light emitting diodes LED including a first light emitting diode and a second light emitting diode which emit the same color light can be disposed. Specifically, in each of the plurality of sub pixels SP, the plurality of light emitting diodes LED including the first light emitting diode LEDa and the second light emitting diode LEDb which emit the same color light can be disposed. For example, in the red sub pixel SPR, a first red light emitting diode 120a and a second red light emitting diode 120b which emit the same red light can be disposed. In the green sub pixel SPG, a first green light emitting diode 130a and a second green light emitting diode 130b which emit the same green light can be disposed. In the blue sub pixel SPB, a first blue light emitting diode 140a and a second blue light emitting diode 140b which emit the same blue light can be disposed.

For example, the first light emitting diode LEDa includes the first red light emitting diode 120a, the first green light emitting diode 130a, and the first blue light emitting diode 140a. The second light emitting diode LEDb includes the second red light emitting diode 120b, the second green light emitting diode 130b, and the second blue light emitting diode 140b.

For example, the light emitting diode LED is configured by the first light emitting diode LEDa and the second light emitting diode LEDb to drive the first light emitting diode LEDa and the second light emitting diode LEDb in each sub pixel SP. For example, the first light emitting diode LEDa and the second light emitting diode LEDb can be connected to different transistors. Therefore, the transistors connected to the first light emitting diode LEDa and the second light emitting diode LEDb are independently driven according to the mode of the display device 100 so that the first light emitting diode LEDa and the second light emitting diode LEDb can be selectively driven.

At this time, the mode can be specified by the user's input or determined when a predetermined condition is satisfied. For example, when a predetermined first condition is satisfied, the first light emitting diode LEDa can emit light as a first mode signal is supplied. When a predetermined second condition is satisfied, the second light emitting diode LEDb can emit light as a second mode signal is supplied. The first condition can include a condition which is specified in advance to be driven in the first mode. The second condition can include a condition which is specified in advance to be driven in the second mode. For example, the first condition can be a state in which the vehicle is stopped and the second condition can be a state in which the vehicle is being driven. Accordingly, the first light emitting diode LEDa can be driven in a vehicle stop state and the second light emitting diode LEDb can be driven in a vehicle driving state, but the present disclosure is not limited thereto and in the vehicle stop state, both the first light emitting diode LEDa and the second light emitting diode LEDb can be driven.

The first light emitting diode LEDa can be configured to allow light emitted from the first light emitting diode LEDa to have a wide viewing angle in a driver seat direction and a front passenger seat direction. Accordingly, light emitted from the first light emitting diode LEDa can be visible to both the driver and the passenger.

The second light emitting diode LEDb can be configured to allow light emitted from the second light emitting diode LEDb to have a narrow viewing angle in a driver seat direction and a wide viewing angle in a front passenger seat direction. Accordingly, light emitted from the second light emitting diode LEDb can be not visible to the driver, but is visible to the passenger.

An area of each sub pixel SP in which the first light emitting diode LEDa is disposed can be defined as a first area A1 and an area of each sub pixel SP in which the second light emitting diode LEDb is disposed can be defined as a second area A2.

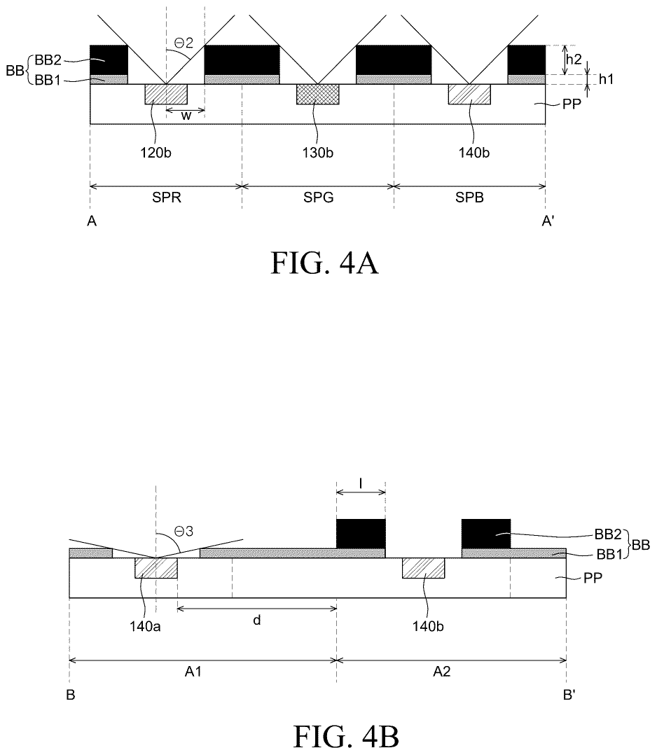

A black bank BB can be disposed in each of the plurality of sub pixels SP. The black bank BB can be disposed to be spaced apart from the light emitting diode LED (such as the second red light emitting diode 120b, the second green light emitting diode 130b, the first blue light emitting diode 140a and the second blue light emitting diode 140b as shown in FIGS. 4A and 4B) and enclose the light emitting diode LED. The black bank BB can be disposed so as to enclose each of the plurality of sub pixels SP to shield the light emitted from each sub pixel SP so as not to be mixed or interfered and suppress the external light reflection.

The black bank BB is configured by a first black bank BB1 and a second black bank BB2. The first black bank BB1 is spaced apart from the plurality of light emitting diodes LED and configured to enclose the first light emitting diode LEDa and the second light emitting diode LEDb. The first black bank BB1 can include a black material. The second black bank BB2 is disposed on the first black bank BB1 and configured to enclose the second light emitting diode LEDb. The second black bank BB2 can include the black material.

In FIG. 3, in order to distinguish placement areas of a first black bank BB1 and a second black bank BB2, the first black bank BB1 is illustrated with gray, rather than black, and the second black bank BB2 is illustrated with black.

The viewing angles of the first light emitting diode LEDa and the second light emitting diode LEDb will be described in detail below with reference to FIGS. 4A and 4B.

With the black bank BB including the first black bank BB1 and the second black bank BB2, the viewing angles of the first light emitting diode LEDa and the second light emitting diode LEDb can be restricted. For example, the black bank BB can be configured have different heights in the first area A1 and the second area A2 to adjust the viewing angles of the first light emitting diode LEDa and the second light emitting diode LEDb. At this time, configurations of black banks BB disposed in the first area A1 which requires a wide field of view and the second area A2 which requires a narrow field of view can be different. For example, with reference to FIG. 4B, the first black bank BB1 is disposed in both the first area A1 and the second area A2 to enclose both the first light emitting diode LEDa and the second light emitting diode LEDb, but the second black bank BB2 can be disposed only in the second area A2 so as to enclose only the second light emitting diode LEDb. Therefore, the black bank BB can have different heights in the first area A1 and the second area A2, respectively. The height of the black bank BB disposed in the second area A2 can be higher than the height of the black bank BB disposed in the first area A1.

At this time, the second light emitting diode LEDb can be disposed to be spaced apart from the first black bank BB1 and the second black bank BB2 with the same distance. For example, a shortest horizontal distance between the second light emitting diode LEDb and the first black bank BB1, for example, a shortest distance d1 on the plane can be equal to a shortest horizontal distance between the second light emitting diode LEDb and the second black bank BB2, for example, a shortest distance d2 on the plane. Accordingly, a viewing angle of the second light emitting diode LEDb can be restricted by the first black bank BB1 and the second black bank BB2.

In contrast, the second black bank BB2 is disposed so as to enclose the second light emitting diode LEDb so that the second light emitting diode LEDb is disposed more adjacent to the first black bank BB1 than the second black bank BB2. For example, a shortest distance d3 on the plane between the first light emitting diode LEDa and the second black bank BB2 can be longer than a shortest distance d2 on the plane between the second light emitting diode LEDb and the second black bank BB2. Therefore, the viewing angle of the first light emitting diode LEDa can be restricted only by the first black bank BB1.

In the meantime, as the height of the black bank BB is higher, the viewing angle of the light emitting diode LED is restricted so that the first area A1 in which the height of the black bank BB is relatively low can be referred to as a wide field of view portion or a wide field of view area. In contrast, the second area A2 in which the height of the black bank BB is relatively high can be referred to as a narrow field of view portion or a narrow field of view area, but is not limited thereto.

Hereinafter, the viewing angles of the black bank BB, the first light emitting diode LEDa, and the second light emitting diode LEDb will be described with reference to FIGS. 4A and 4B.

FIG. 4A is a cross-sectional view taken along A-A′ of FIG. 3. FIG. 4B is a cross-sectional view taken along B-B′ of FIG. 3. In FIGS. 4A and 4B, for the convenience of description, only a panel portion PP, the first light emitting diode LEDa, the second light emitting diode LEDb, the first black bank BB1, and the second black bank BB2 are illustrated.

Referring to FIGS. 4A and 4B, the panel portion PP can be disposed. The panel portion PP can include various components for driving the light emitting diode LED. For example, the panel portion PP can include a substrate which supports various components including the light emitting diode LED, a driving transistor which drives a light emitting diode LED, and various insulating layers.

Referring to FIGS. 4A and 4B, the first light emitting diode LEDa and the second light emitting diode LEDb can be disposed on the panel portion PP. Each of the first light emitting diode LEDa and the second light emitting diode LEDb can be a vertical light emitting diode in which a first electrode, a first semiconductor layer, an emission layer, a second semiconductor layer, and a second electrode are sequentially laminated, but is not limited thereto.

In the meantime, in FIGS. 4A and 4B, for the convenience of illustration, it is illustrated that the panel portion PP encloses three surfaces excluding a top surface of the light emitting diode LED, but the present disclosure is not limited thereto. Therefore, the light emitting diode LED can be disposed on the panel portion PP, in a different manner as illustrated in FIG. 4A and 4B.

The black bank BB can be disposed on the panel portion PP. The black bank BB can be disposed to be spaced apart from the light emitting diode LED so as to enclose the light emitting diode LED. The black bank BB is disposed so as to enclose each of the plurality of sub pixels SP to shield the light emitted from each sub pixel SP so as not to be mixed or interfered and suppress the external light reflection.

The black bank BB can limit the viewing angles of the first light emitting diode LEDa and the second light emitting diode LEDb. For example, the black bank BB can include a first black bank BB1 and a second black bank BB2 disposed on the first black bank BB1. At this time, the first black bank BB1 can be disposed so as to enclose both the first light emitting diode LEDa and the second light emitting diode LEDb, but the second black bank BB2 can be disposed so as to enclose only the second light emitting diode LEDb. Therefore, the viewing angle of the first light emitting diode LEDa can be restricted only by the first black bank BB1 and the viewing angle of the second light emitting diode LEDb can be restricted by the first black bank BB1 and the second black bank BB2.

Specifically, the viewing angles of the first light emitting diode LEDa and the second light emitting diode LEDb can be determined by an interval between the first light emitting diode LEDa and the second light emitting diode LEDb and the black bank BB and the height of the black bank BB. At this time, the viewing angles of the first light emitting diode LEDa and the second light emitting diode LEDb refer to a maximum angle between light emitted from the first light emitting diode LEDa and the second light emitting diode LEDb and a normal line of the display device 100. Therefore, the first light emitting diode LEDa and the second light emitting diode LEDb can have viewing angles within the range of the maximum angle. For example, when the viewing angle of the second light emitting diode LEDb is θ2, a height of the first black bank BB1 is h1, a height of the second black bank BB2 is h2, and an interval between a center of the light emitting diode LED and an end of the black bank BB that is closer to the light emitting diode LED is w, tan θ2 is w/(h1+h2) so that a viewing θ2 of the second light emitting diode LEDb can be tan⁻¹(w/(h1+h2)).

Referring to FIG. 4B, when the viewing angle of the first light emitting diode LEDa is θ3, tan θ3 is w/h1 so that a viewing angle θ3 of the first light emitting diode LEDa can be tan⁻¹(w/h1). Accordingly, the viewing angle θ2 of the second light emitting diode LEDb which is disposed in an area in which the height of the black bank BB is relatively high can be narrower than the viewing angle θ3 of the first light emitting diode LEDa disposed in an area in which the height of the black bank BB is relatively low.

For example, a width of one sub pixel SP is assumed as 50.7 μm. At this time, a center of the first light emitting diode LEDa can be spaced apart from an end of the first black bank BB1 by the interval w of approximately 10 μm and a center of the second light emitting diode LEDb can be spaced apart from ends of the first black bank BB1 and the second black bank BB2 by the interval w of approximately 10 μm.

At this time, when the height of the black bank BB is 12 μm, for example, when the height h1 of the first black bank BB1 is 2 μm and the height h2 of the second black bank BB2 is 10 μm or when the height h1 of the first black bank BB1 is 1 μm and the height h2 of the second black bank BB2 is 11 μm, the viewing angle θ3 of the first light emitting diode LEDa can be approximately 80° or larger and the viewing angle θ2 of the second light emitting diode LEDb can be approximately 40° or smaller.

At this time, in order not to interfere a viewing angle characteristic of the first light emitting diode LEDa with the second black bank BB2, the first light emitting diode LEDa can be disposed to be spaced apart from the second black bank BB2 with a predetermined interval therebetween. For example, it is assumed that a minimum distance between the first light emitting diode LEDa (such as the first blue light emitting diode 140a as shown in FIG. 4B) and the second black bank BB2 is d. When a height of the first black bank BB1 is 2 μm, d for implementing the viewing angle of the first light emitting diode LEDa to at least approximately 80° can be approximately 60 μm. For example, the first light emitting diode LEDa and the second black bank BB2 can be disposed to be spaced apart from each other by at least 60 μm, but the present disclosure is not limited thereto.

Further, a width of the second black bank BB2, for example, a horizontal width l of the second black bank BB2 can also be determined in the range which does not impede the viewing angle characteristic of the first light emitting diode LEDa. In other words, the horizontal width l of the second black bank BB2 can be designed in consideration of the viewing angle characteristic of the first light emitting diode LEDa, but is not limited thereto.

In the meantime, in FIGS. 4A and 4B, it is described that the black bank BB includes the first black bank BB1 and the second black bank BB2, but the present disclosure is not limited thereto and the black bank BB can be formed with a single configuration, for example, a single bank.

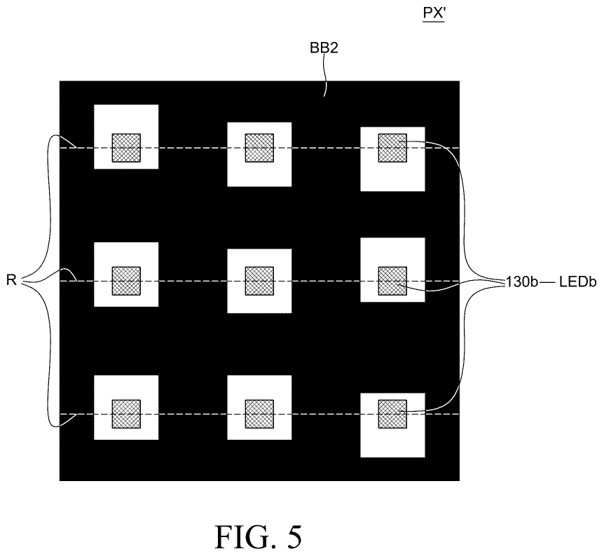

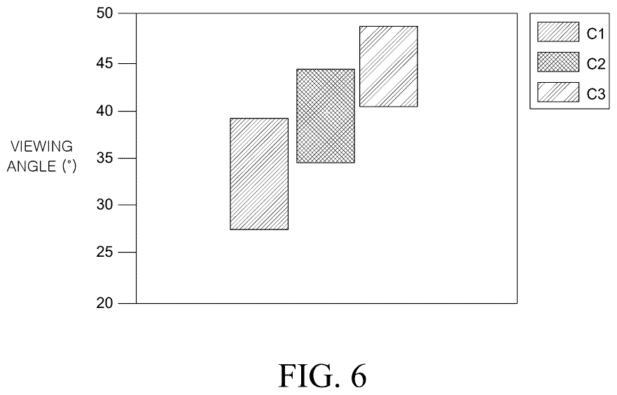

FIG. 5 is an enlarged plan view of a predetermined unit pixel PX′ of a display device according to an example embodiment of the present disclosure. FIG. 6 is a distribution chart of a viewing angle of the predetermined unit pixel PX′ of a display device according to an example embodiment of the present disclosure. In FIG. 5, for the convenience of description, only the second area A2 disposed in the predetermined unit pixel PX′ in which the second light emitting diode LEDb is disposed is illustrated and a blue sub pixel SPB is illustrated as an example. Plan views of a red sub pixel SPR and a green sub pixel SPG can also be substantially the same as the blue sub pixel SPB.

In FIG. 6, by assuming that a transfer tolerance of the light emitting diode LED is approximately ±2 μm, a viewing angle distribution chart of the predetermined unit pixel PX′ in which black banks BB are randomly disposed along a uniform random function in the transfer error range is illustrated. Specifically, in a first case C1, the second light emitting diode LEDb is transferred by being shifted from a correct position R by −2 μm. In a second case C2, the second light emitting diode LEDb is transferred in the correction position R. In a third case C3, the second light emitting diode LEDb is transferred by being shifted from the correct position R by +2 μm.

Referring to FIG. 5, a distance between the second black bank BB2 and an adjacent pixel PX or sub pixel SP with respect to the predetermined unit pixel PX′ may not be constant, but can be random or non-uniform. For example, the predetermined unit pixel PX′, as illustrated in FIG. 5, can be formed by 3×3 sub pixels SP. However, the predetermined unit pixel PX′ is not limited thereto, but can be formed by 4×4 sub pixels SP.

Specifically, as described above, the viewing angle θ3 of the first light emitting diode LEDa is tan⁻¹(w/h1) and the viewing angle θ2 of the second light emitting diode LEDb is tan⁻¹(w/(h1+h2)) so that in the second light emitting diode LEDb having a relatively narrow viewing angle, the viewing angle can greatly vary according to the interval w. For example, due to the transfer tolerance of the light emitting diode LED, the light emitting diode LED can be disposed to be shifted from the correct position R. In this case, as the interval w has a deviation, a viewing angle deviation can be generated.

In the meantime, positions of the driver and the passenger are distinguished based on a horizontal direction, rather than the vertical direction so that the viewing angles of the driver and the passenger can be affected by the horizontal direction, rather than the vertical direction. Therefore, in FIGS. 3 and 5, it is assumed that the direction B-B′ of FIG. 3 corresponds to the direction of the driver/passenger and the light emitting diode LED is transferred to be shifted up and down from the correct position R.

For example, when the first light emitting diode LEDa is transferred to be shifted within ±2 μm from the correct position R, a viewing angle deviation of ±1° can occur. In contrast, when the second light emitting diode LEDb is transferred to be shifted within ±2 μm from the correct position R, a viewing angle deviation can be approximately ±5° which is relatively large. Such a deviation can be recognized by a user of the display device 100 as spots.

Therefore, the second black banks BB2 can be randomly disposed by assuming the uniform random function within a transfer error range of the light emitting diode LED. For example, the second black bank BB2 can be randomly disposed with a predetermined deviation in one direction with respect to an mean position within the predetermined unit pixel PX′. At this time, an average of the deviation can converge to 0.

Specifically, the second black banks BB2 are randomly disposed in the predetermined unit pixel PX′ so that shortest distances d2 on the plane between the second light emitting diodes LEDb and the second black bank BB2 disposed in the predetermined unit pixel PX′ can be different. Therefore, the viewing angles of the second light emitting diodes LEDb disposed in the predetermined unit pixel PX′ can be distributed within various ranges. The viewing angles of the second light emitting diodes LEDb can partially overlap each other. For example, the viewing angles of the second light emitting diodes LEDb disposed in the predetermined unit pixel PX′ can be continuously distributed. Accordingly, the second black bank BB2 can minimize the problem in that the spots caused by the viewing angle deviation between the second light emitting diodes LEDb disposed in the predetermined unit pixel PX′ is recognized.

Specifically, referring to FIG. 6 together, a viewing angle of the second light emitting diode LEDb of the first case C1 can be distributed in the range of approximately 27° or larger and 40° or smaller. A viewing angle of the second light emitting diode LEDb of the second case C2 can be distributed in the range of approximately 33° or larger and 45° or smaller. Therefore, the viewing angle of the second light emitting diode LEDb of the second case C2 can overlap the viewing angle of the second light emitting diode LEDb of the first case C1 in the range of 33° or larger and 40° or smaller. A viewing angle of the second light emitting diode LEDb of the third case C3 can be distributed in the range of approximately 40° or larger and 50° or smaller. Therefore, the viewing angle of the second light emitting diode LEDb of the third case C3 can overlap the viewing angle of the second light emitting diode LEDb of the second case C2 in the range of 40° or larger and 45° or smaller.

For example, the viewing angle of the second light emitting diode LEDb in the predetermined unit pixel PX′ can be continuously distributed. Accordingly, the problem in that the spot is recognized according to the viewing angle deviation of the second light emitting diode LEDb can be minimized.

A co-driver display can be disposed on the vehicle dash board in the front direction of the front passenger seat to provide convenience for a passenger in the front passenger seat. For example, the co-driver display can provide information which is irrelevant to the vehicle operation, for example, information about entertainment, such as dramas, movies, or music. However, in order to ensure the safety of the vehicle operation, the co-driver display needs to selectively provide images to a direction in which the driver seat is disposed. For example, the co-driver display can control the viewing angle to allow the driver and the passenger to watch the images in a vehicle stop state together and control the viewing angle to allow only the passenger to watch the images in a vehicle driving state. For example, the co-driver display needs to control the viewing angle to have different viewing angles in the vehicle stop state and the vehicle driving state.

In the display device 100 according to the example embodiment of the present disclosure, in each of the plurality of sub pixels SP, the first light emitting diode LEDa and the second light emitting diode LEDb can be selectively driven. Specifically, each sub pixel SP can include a first area A1 in which the first light emitting diode LEDa is disposed and a second area A2 in which the second light emitting diode LEDb is disposed. At this time, in the first area A1 and the second area A2, the height of the black bank BB is differently adjusted to adjust the viewing angles of the first light emitting diode LEDa and the second light emitting diode LEDb. For example, the first area A1 in which the first light emitting diode LEDa is disposed requires a wide field of view and only the first black bank BB1 can be disposed in the first area A1. Further, the second area A2 in which the second light emitting diode LEDb is disposed requires a narrow field of view and not only the first black bank BB1, but also the second black bank BB2 can be disposed in the second area A2. For example, in the first area A1, the black bank BB is disposed to be relatively low to implement a wide viewing angle and in the second area A2, the black bank BB is disposed to be relatively high to implement a narrow viewing angle. Accordingly, in the display device 100 according to the example embodiment of the present disclosure, the height of the black bank BB is adjusted to selectively have a narrow viewing angle in a specific area.

Further, in the display device 100 according to the example embodiment of the present disclosure, the viewing angles of the first light emitting diode LEDa and the second light emitting diode LEDb can be controlled using only the black bank BB. Accordingly, in the display device 100 according to the example embodiment of the present disclosure, a separate component for controlling a viewing angle can be unnecessary to reduce a manufacturing process of the display device 100 to reduce a manufacturing cost and a product cost.

Specifically, in the display device 100 according to the example embodiment of the present disclosure, in the second area A2 in which the narrow viewing angle is implemented, the second black banks BB2 can be randomly disposed. For example, the second black banks BB2 can be randomly disposed by assuming the uniform random function within a transfer error range of the light emitting diode LED with respect to the predetermined unit pixel PX′. Therefore, the shortest distance between the second light emitting diode LEDb and the second black bank BB2 disposed in the predetermined unit pixel PX′ can be different. Accordingly, the viewing angles of the second light emitting diodes LEDb disposed in the corresponding pixel PX can be distributed within various ranges. Therefore, the viewing angles of the second light emitting diodes LEDb can partially overlap each other. For example, the viewing angles of the second light emitting diodes LEDb disposed in the predetermined unit pixel PX′ can be continuously distributed. Accordingly, even though the second light emitting diode LEDb is shifted from the correct position due to the transfer error, the problem in that the spots due to the viewing angle deviation between the second light emitting diodes LEDb are recognized can be minimized. Accordingly, a display quality of the display device 100 according to the example embodiment of the present disclosure can be improved.

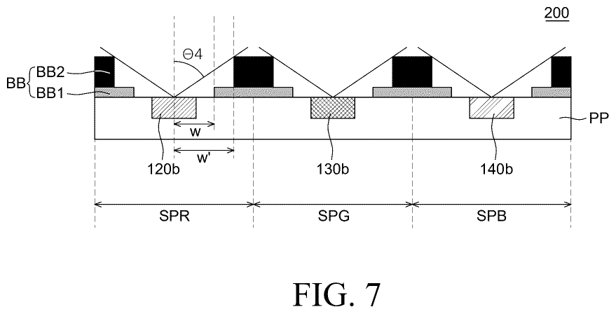

FIG. 7 is a cross-sectional view of a sub pixel of a display device according to another example embodiment of the present disclosure and is a cross-sectional view of another example embodiment taken along A-A′ of FIG. 3. The only difference or a main difference between a display device 200 of FIG. 7 and the display device 100 of FIGS. 1 to 6 is a black bank BB, but the other components are the same or substantially the same, so that a redundant description will be omitted or may be briefly provided.

Referring to FIG. 7, a width of the second black bank BB2 can be narrower than a width of the first black bank BB1. Accordingly, the second black bank BB2 can expose at least a part of the first black bank BB1. For example, an end of the first black bank BB1 and an end of the second black bank BB2 can be disposed on different planes.

Therefore, the second light emitting diode LEDb can be disposed to be adjacent to the first black bank BB1 more than the second black bank BB2. In other words, an interval w′ between the second light emitting diode LEDb and the second black bank BB2 can be larger than an interval w between the second light emitting diode LEDb and the first black bank BB1. Accordingly, the shortest distance d2 on the plane between the second light emitting diode LEDb and the second black bank BB2 can be longer than the shortest distance d1 on the plane between the second light emitting diode LEDb and the first black bank BB1.

For example, when the width of the second black bank BB2 and the width of the first black bank BB1 are equal, the second black bank BB2 protrudes from the first black bank BB1 due to the process error. At this time, the interval w′ between the second light emitting diode LEDb and the second black bank BB2 can vary so that the viewing angle deviation between the second light emitting diodes LEDb can occur. Accordingly, the width of the second black bank BB2 is formed to be smaller than the width of the first black bank BB1, so that the second black bank BB2 may not protrude from the first black bank BB1. Accordingly, the error occurring for the interval w′ between the second light emitting diode LEDb and the second black bank BB2 is minimized to minimize the viewing angle deviation caused between the second light emitting diodes LEDb.

In the display device 200 according to another example embodiment of the present disclosure, the first light emitting diode LEDa and the second light emitting diode LEDb which are selectively driven can be disposed in one sub pixel SP. At this time, in the first area A1 in which the first light emitting diode LEDa is disposed, only the first black bank BB1 can be disposed and in the second area A2 in which the second light emitting diode LEDb is disposed, not only the first black bank BB1, but also the second black bank BB2 can be disposed. For example, in the first area A1, the black bank BB is disposed to be relatively low to implement a wide viewing angle and in the second area A2, the black bank BB is disposed to be relatively high to implement a narrow viewing angle. Accordingly, in the display device 200 according to another example embodiment of the present disclosure, the height of the black bank BB is adjusted to selectively have a narrow viewing angle in a specific area.

Further, in the display device 200 according to another example embodiment of the present disclosure, the viewing angles of the first light emitting diode LEDa and the second light emitting diode LEDb can be controlled using only the black bank BB. Accordingly, in the display device 200 according to another example embodiment of the present disclosure, a separate component for controlling a viewing angle is not required so that the manufacturing process of the display device 200 is simplified to save the cost.

Specifically, in the display device 200 according to another example embodiment of the present disclosure, in the second area A2 in which the narrow viewing angle is implemented, the distance between the second black bank BB2 and the adjacent pixel PX or sub pixel SP may not be constant, but can be random. For example, the second black banks BB2 can be randomly disposed by assuming the uniform random function within a transfer error range of the light emitting diode LED with respect to the predetermined unit pixel PX′. Accordingly, the viewing angles of the second light emitting diodes LEDb disposed in the corresponding pixel PX can be distributed within various ranges. Therefore, the viewing angles of the second light emitting diodes LEDb can partially overlap each other. For example, the viewing angle of the second light emitting diode LEDb disposed in the predetermined unit pixel PX′ can be continuously distributed. Accordingly, even though the second light emitting diode LEDb is shifted from the correct position R due to the transfer error, the problem in that the spots due to the viewing angle deviation between the second light emitting diodes LEDb are recognized can be minimized. Accordingly, a display quality of the display device 200 according to another example embodiment of the present disclosure can be improved.

Specifically, as shown in FIG. 7, in the display device 200 according to another example embodiment of the present disclosure, the width of the second black bank BB2 can be formed to be smaller than the width of the first black bank BB1. Accordingly, the second black bank BB2 can be disposed so as not to protrude from the first black bank BB1. Therefore, the error occurring in the interval w′ between the second light emitting diode LEDb and the second black bank BB2 can be minimized. For example, in the display device 200 according to another example of the present disclosure, the viewing angle deviation between the second light emitting diodes LEDb due to the process error occurring during the formation of the black bank BB is minimized. As a result, the problem in that the spot caused by the viewing angle deviation is recognized can be minimized.

The example embodiments of the present disclosure can also be described as follows:

According to an aspect of the present disclosure, there is provided a display device. The display device includes a substrate in which a plurality of pixels each including a plurality of sub pixels is defined. The display device further includes a plurality of light emitting diodes which is disposed in each of the plurality of sub pixels and includes a first light emitting diode and a second light emitting diode which emit the same color light. The display device further includes a first bank which is spaced apart from the plurality of light emitting diodes so as to enclose the first light emitting diode and the second light emitting diode and includes a black material. The display device further includes a second bank which is disposed on the first bank, is disposed so as to enclose the second light emitting diode, and includes the black material.

In each of the plurality of sub pixels, the first light emitting diode and the second light emitting diode can be selectively driven.

The second bank can be randomly disposed with a predetermined deviation in one direction with respect to an mean position, in a predetermined unit pixel.

The predetermined unit pixel can be 3×3 or 4×4 sub pixel units.

In in the predetermined unit pixel, an average of the deviation can converge to 0.

Viewing angles of the second light emitting diodes disposed in the predetermined unit pixel can at least partially overlap each other.

A shortest distance on the plane between the first light emitting diode and the second bank can be longer than a shortest distance on the plane between the second light emitting diode and the second bank.

A shortest distance on the plane between the second light emitting diode and the first bank can be equal to a shortest distance on the plane between the second light emitting diode and the second bank.

A shortest distance on the plane between the second light emitting diode and the second bank can be longer than a shortest distance on the plane between the second light emitting diode and the first bank.

The second bank can expose at least a part of the first bank.

According to another aspect of the present disclosure, there is provided a display device. The display device includes a substrate in which a plurality of pixels including a plurality of sub pixels is defined. The display device further includes a plurality of light emitting diodes which is disposed in each of the plurality of pixels and includes a first light emitting diode and a second light emitting diode which emit the same color light. The display device further includes a black bank which is disposed so as to enclose the plurality of light emitting diodes in each of the plurality of pixels. The plurality of sub pixels includes a first area in which the first light emitting diode is disposed, and a second area in which a second light emitting diode emitting the same color light as the first light emitting diode is disposed. The black bank has different heights in the first area and the second area, respectively.

A height of the black bank disposed in the second area can be higher than a height of the black bank disposed in the first area.

The black bank can include a first black bank disposed in the first area and the second area, and a second black bank disposed on the first black bank in the second area.

The second black bank is randomly disposed in a predetermined unit pixel.

Shortest distances on the plane between the second light emitting diodes and the second black bank disposed in the predetermined unit pixel can be different.

The second light emitting diode is disposed to be spaced apart from the first black bank and the second black bank with the same distance.

The second light emitting diode can be disposed more adjacent to the first black bank than the second black bank.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure.

What is claimed is:

1. A display device, comprising:
a substrate in which a plurality of pixels are provided, each of the plurality of pixels including a plurality of sub pixels;
a plurality of light emitting diodes disposed in each of the plurality of sub pixels, and including a first light emitting diode and a second light emitting diode that are configured to emit a same color light;
a first bank spaced apart from the plurality of light emitting diodes, and configured to enclose the first light emitting diode and the second light emitting diode, the first bank including a black material; and
a second bank disposed on the first bank, and configured to enclose the second light emitting diode, the second bank including the black material.

2. The display device according to claim 1, wherein in each of the plurality of sub pixels, the first light emitting diode and the second light emitting diode are configured to be selectively driven.

3. The display device according to claim 1, wherein the second bank is randomly disposed with a predetermined deviation in one direction with respect to a mean position, in a predetermined unit pixel.

4. The display device according to claim 3, wherein the predetermined unit pixel is 3×3 sub pixel units or 4×4 sub pixel units.

5. The display device according to claim 3, wherein in the predetermined unit pixel, an average of the predetermined deviation converges to 0.

6. The display device according to claim 3, wherein viewing angles of the second light emitting diodes disposed in the predetermined unit pixel at least partially overlap each other.

7. The display device according to claim 1, wherein a shortest distance on a plane between the first light emitting diode and the second bank is longer than a shortest distance on a plane between the second light emitting diode and the second bank.

8. The display device according to claim 1, wherein a shortest distance on a plane between the second light emitting diode and the first bank is equal to a shortest distance on a plane between the second light emitting diode and the second bank.

9. The display device according to claim 1, wherein a shortest distance on a plane between the second light emitting diode and the second bank is longer than a shortest distance on a plane between the second light emitting diode and the first bank.

10. The display device according to claim 9, wherein the second bank is configured to expose at least a part of the first bank.

11. A display device, comprising:
a substrate in which a plurality of pixels including a plurality of sub pixels are defined;
a plurality of light emitting diodes disposed in each of the plurality of pixels, and including a first light emitting diode and a second light emitting diode that are configured to emit a same color light; and
a black bank disposed to enclose the plurality of light emitting diodes in each of the plurality of pixels,
wherein the plurality of sub pixels include:
a first area in which the first light emitting diode is disposed; and
a second area in which the second light emitting diode configured to emit the same color light as the first light emitting diode is disposed, and
wherein the black bank has different heights in the first area and the second area, respectively.

12. The display device according to claim 11, wherein a height of the black bank disposed in the second area is higher than a height of the black bank disposed in the first area.

13. The display device according to claim 11, wherein the black bank includes:
a first black bank disposed in the first area and the second area; and
a second black bank disposed on the first black bank in the second area.

14. The display device according to claim 13, wherein the second black bank is randomly disposed in a predetermined unit pixel.

15. The display device according to claim 14, wherein shortest distances on a plane between the second light emitting diodes and the second black bank disposed in the predetermined unit pixel are different from each other.

16. The display device according to claim 13, wherein the second light emitting diode is disposed to be spaced apart from the first black bank and the second black bank with a same distance.

17. The display device according to claim 13, wherein the second light emitting diode is disposed more adjacent to the first black bank than the second black bank.

18. The display device according to claim 14, wherein the predetermined unit pixel is 3×3 sub pixel units or 4×4 sub pixel units.

19. The display device according to claim 11, wherein a top surface of the first or second light emitting diode is coplanar with a bottom surface of the black bank.
